(19) United States
(12) Patent Application Publication
(10) Pub. No.: US 2005/0260354 A1
(43) Pub. Date: Nov. 24, 2005

(54) In-situ process chamber preparation methods for plasma ion implantation systems

(75) Inventors: Vikram Singh, North Andover, MA (US); Atul Gupta, Beverly, MA (US); Harold M. Persing, Rockport, MA (US); Steven R. Walther, Andover, MA (US); Anne L. Testoni, Bolton, MA (US)

Correspondence Address: Mark A. Superko, Esq.;Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 10/850,222

(22) Filed: May 20, 2004

(51) Int. Cl. C23C 14/00; C23C 16/00

(52) U.S. Cl. 427/523; 118/723 R

(57) ABSTRACT

A method for plasma ion implantation of a substrate includes providing a plasma ion implantation system including a process chamber, a source for producing a plasma in the process chamber, a platen for holding the substrate in the process chamber, and a voltage source for accelerating ions from the plasma into the substrate, depositing on interior surfaces of the process chamber a fresh coating that is similar in composition to a deposited film that results from plasma ion implantation of the substrate, before depositing the fresh coating, cleaning interior surfaces of the process chamber by removing an old film using one or more activated cleaning precursors, plasma ion implantation of the substrate according to a plasma ion implantation process, and repeating the steps of cleaning interior surfaces of the process chamber and depositing a fresh coating following plasma ion implantation of one or more substrates.

### FIELD OF THE INVENTION

This invention relates to systems and methods for plasma ion implantation of substrates and, more particularly, to methods for preparing a process chamber for plasma ion implantation. The preparation methods may include a cleaning process, a coating process, or both.

### BACKGROUND OF THE INVENTION

Ion implantation is a standard technique for introducing conductivity-altering impurities into semiconductor wafers. In a conventional beamline ion implantation system, a desired impurity material is ionized in an ion source, the ions are accelerated to form an ion beam of prescribed energy, and the ion beam is directed at the surface of the wafer. Energetic ions in the beam penetrate into the bulk of the semiconductor material and are embedded into the crystalline lattice of the semiconductor material to form a region of desired conductivity.

A well-known trend in the semiconductor industry is toward smaller, higher speed devices. In particular, both the lateral dimensions and the depths of features in semiconductor devices are decreasing. The implanted depth of the dopant material is determined, at least in part, by the energy of the ions implanted into the semiconductor wafer. Beamline ion implanters are typically designed for efficient operation at relatively high implant energies and may not function efficiently at the low energies required for shallow junction implantation.

Plasma doping systems have been studied for forming shallow junctions in semiconductor wafers. In a plasma doping system, a semiconductor wafer is placed on a conductive platen, which functions as a cathode and is located in a process chamber. An ionizable process gas containing the desired dopant material is introduced into the chamber, and a voltage pulse is applied between the platen and an anode or the chamber walls, causing formation of a plasma having a plasma sheath in the vicinity of the wafer. The applied pulse causes ions in the plasma to cross the plasma sheath and to be implanted into the wafer. The depth of implantation is related to the voltage applied between the wafer and the anode. Very low implant energies can be achieved. Plasma doping systems are described, for example, in U.S. Pat. No. 5,354,381, issued Oct. 11, 1994 to Sheng; U.S. Pat. No. 6,020,592, issued Feb. 1, 2000 to Liebert et al.; and U.S. Pat. No. 6,182,604, issued Feb. 6, 2001 to Goeckner et al.

In the plasma doping systems described above, the applied voltage pulse generates a plasma and accelerates positive ions from the plasma toward the wafer. In other types of plasma systems, known as plasma immersion systems, continuous or pulsed RF energy is applied to the process chamber, thus producing a continuous or pulsed plasma. At intervals, negative voltage pulses, which may be synchronized with the RF pulses, are applied to the platen, causing positive ions in the plasma to be accelerated toward the wafer.

Process control in substrate processing systems is known to be very sensitive to the condition of the process chamber. For good process repeatability, the process chamber should be kept at constant conditions. However, during substrate processing, the process chamber condition may drift because of interactions with the plasma. Material can be removed from the surface by etching or sputtering, or material can accumulate by deposition under different operating conditions. Accordingly, the process chamber condition should be controlled in order to obtain a repeatable process. The problems to be solved in connection with controlling the chamber condition include restoring the chamber to a fixed condition between implants for wafer-to-wafer repeatability, restoring the chamber condition after any maintenance and/or chamber cleaning, and limiting contamination of implanted wafers with undesired elements, such as metals and/or dopants from prior processing when a different dopant was utilized. These elements originate from the hardware components of the process chamber and may be transported to wafers during the implant.

### SUMMARY OF THE INVENTION

According to a first aspect of the invention, methods and apparatus are provided for plasma ion implantation of a substrate. The method comprises providing a plasma ion implantation system including a process chamber, a source for producing a plasma in the process chamber, a platen for holding the substrate in the process chamber, and a voltage source for accelerating ions from the plasma into the substrate, depositing on interior surfaces of the process chamber a coating that is compatible with a plasma ion implantation process performed in the process chamber, and plasma ion implantation of the substrate according to the plasma ion implantation process. The coating may contain a substrate material such as silicon.

According to a second aspect of the invention, methods and apparatus are provided for plasma ion implantation of a substrate. The method comprises providing a plasma ion implantation system including a process chamber, a source for producing a plasma in the process chamber, a platen for holding a substrate in the process chamber and a voltage source for accelerating ions from the plasma into the substrate, depositing on interior surfaces of the process chamber a coating that is compatible with a plasma ion implantation process performed in the process chamber, wherein depositing a coating comprises depositing a dopant-containing coating, and plasma ion implantation of the substrate according to the plasma ion implantation process. The coating may have a composition similar to the composition of the substrate surface during plasma ion implantation.

According to a third aspect of the invention, methods and apparatus are provided for plasma ion implantation of a substrate. The method comprises providing a plasma ion implantation system including a process chamber, a source for producing a plasma in the process chamber, a platen for holding the substrate in the process chamber, and a voltage source for accelerating ions from the plasma into the substrate, depositing on interior surfaces of the process chamber a fresh coating that is similar in composition to a deposited film that results from plasma ion implantation of the substrate, before depositing the fresh coating, cleaning interior surfaces of the process chamber by removing an old film using one or more activated cleaning precursors, plasma ion implantation of the substrate according to a plasma ion implantation process, and repeating the steps of cleaning interior surfaces of the process chamber and depositing a fresh coating following plasma ion implantation of one or more substrates.

According to a fourth aspect of the invention, methods and apparatus are provided for plasma ion implantation of a substrate. The method comprises providing a plasma ion implantation system including a process chamber, a source for producing a plasma in the process chamber, a platen for holding a substrate in the process chamber, and a voltage source for accelerating ions from the plasma into the substrate, cleaning interior surfaces of the process chamber with a cleaning gas that is compatible with a plasma ion implantation process performed in the process chamber, and plasma ion implantation of the substrate according to the plasma ion implantation process.

### BRIEF DESCRIPTION OF THE DRAWINGS

For a better understanding of the present invention, reference is made to the accompanying drawings, which are incorporated herein by reference and in which:

FIG. 1 is a simplified schematic block diagram of a pulsed DC plasma ion implantation system;

FIG. 2 is a high-level flow diagram of a process chamber preparation method in accordance with an embodiment of the invention;

FIG. 3 is a flow diagram of an embodiment of the cleaning process shown in FIG. 2;

FIG. 4 is a flow diagram of an embodiment of the coating process shown in FIG. 2, and

FIG. 5 is a simplified schematic diagram of an RF-based plasma ion implantation process chamber, illustrating techniques for introducing a cleaning gas and a coating precursor gas into the process chamber in accordance with embodiments of the invention.

### DETAILED DESCRIPTION

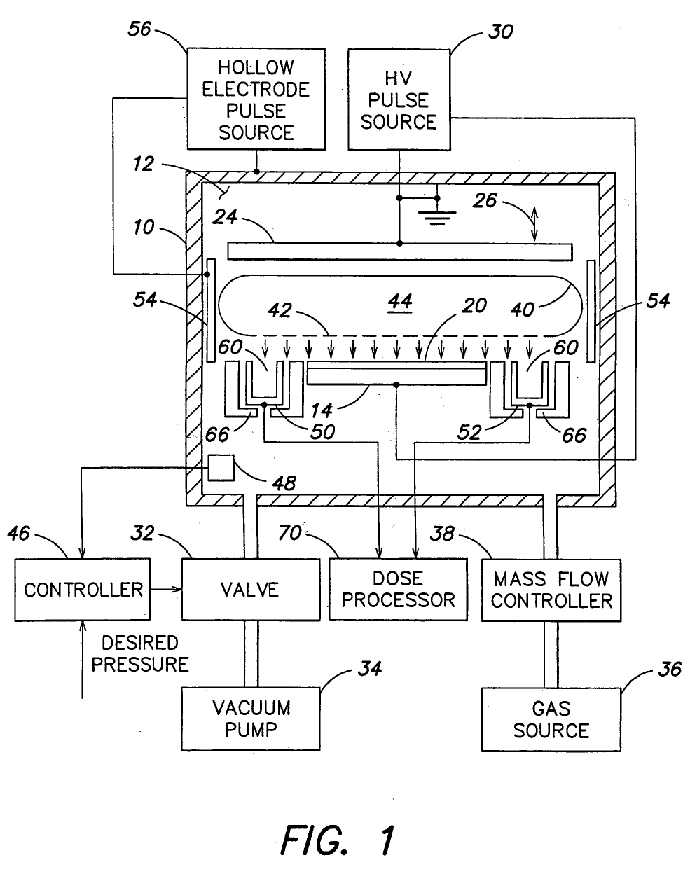

An example of a plasma ion implantation system suitable for implementation of the present invention is shown schematically in FIG. 1. A process chamber 10 defines an enclosed volume 12. A platen 14 positioned within chamber 10 provides a surface for holding a substrate, such as a semiconductor wafer 20. The wafer 20 may, for example, be clamped at its periphery to a flat surface of platen 14 or may be electrostatically clamped. In one embodiment, the platen has an electrically conductive surface for supporting wafer 20. In another embodiment, the platen includes conductive pins (not shown) for connection to wafer 20. In addition, platen 14 may be equipped with a heating/cooling system to control wafer/substrate temperature.

An anode 24 is positioned within chamber 10 in spaced relation to platen 14. Anode 24 may be movable in a direction, indicated by arrow 26, perpendicular to platen 14. The anode is typically connected to electrically conductive walls of chamber 10, both of which may be connected to ground. In another embodiment, platen 14 is connected to ground, and anode 24 is pulsed to a negative voltage. In further embodiments, both anode 24 and platen 14 may be biased with respect to ground.

The wafer 20 (via platen 14) and the anode 24 are connected to a high voltage pulse source 30, so that wafer 20 functions as a cathode. The pulse source 30 typically provides pulses in a range of about 20 to 20,000 volts in amplitude, about 1 to 200 microseconds in duration and a pulse repetition rate of about 100 Hz to 20 kHz. It will be understood that these pulse parameter values are given by way of example only and that other values may be utilized within the scope of the invention.

The enclosed volume 12 of chamber 10 is coupled through a controllable valve 32 to a vacuum pump 34. A process gas source 36 is coupled through a mass flow controller 38 to chamber 10. A pressure sensor 48 located within chamber 10 provides a signal indicative of chamber pressure to a controller 46. The controller 46 compares the sensed chamber pressure with a desired pressure input and provides a control signal to valve 32 or mass flow controller 38. The control signal controls valve 32 or mass flow controller 38 so as to minimize the difference between the chamber pressure and the desired pressure. Vacuum pump 34, valve 32, mass flow controller 38, pressure sensor 48 and controller 46 constitute a closed loop pressure control system. The pressure is typically controlled in a range of about 1 millitorr to about 500 millitorr, but is not limited to this range. Gas source 36 supplies an ionizable gas containing a desired dopant for implantation into the workpiece. Examples of ionizable gas include BF₃, N₂, Ar, PH₃, AsH₃, B₂H₆, PF₃, AsF₅ and Xe. Mass flow controller 38 regulates the rate at which gas is supplied to chamber 10. The configuration shown in FIG. 1 provides a continuous flow of process gas at a desired flow rate and constant pressure. The pressure and gas flow rate are preferably regulated to provide repeatable results. Alternately, in another embodiment the gas flow may be regulated using a valve controlled by controller 46 while valve 32 is kept at a fixed position. Such an arrangement is referred to as upstream pressure control. Other configurations for regulating gas pressure may be utilized.

The plasma doping system may include a hollow cathode 54 connected to a hollow cathode pulse source 56. In one embodiment, the hollow cathode 54 comprises a conductive hollow cylinder that surrounds the space between anode 24 and platen 14. The hollow cathode may be utilized in applications which require very low ion energies. In particular, hollow cathode pulse source 56 provides a pulse voltage that is sufficient to form a plasma within chamber 12, and pulse source 30 establishes a desired implant voltage. Additional details regarding the use of a hollow cathode are provided in the aforementioned U.S. Pat. No. 6,182,604, which is hereby incorporated by reference.

One or more Faraday cups may be positioned adjacent to platen 14 for measuring the ion dose implanted into wafer 20. In the embodiment of FIG. 1, Faraday cups 50, 52, etc. are equally spaced around the periphery of wafer 20. Each Faraday cup comprises a conductive enclosure having an entrance 60 facing plasma 40. Each Faraday cup is preferably positioned as close as is practical to wafer 20 and intercepts a sample of the positive ions accelerated from plasma 40 toward platen 14. In another embodiment, an annular Faraday cup is positioned around wafer 20 and platen 14.

The Faraday cups are electrically connected to a dose processor 70 or other dose monitoring circuit. Positive ions entering each Faraday cup through entrance 60 produce in the electrical circuit connected to the Faraday cup a current that is representative of ion current. The dose processor 70 may process the electrical current to determine ion dose.

The plasma ion implantation system may include a guard ring 66 that surrounds platen 14. The guard ring 66 may be biased to improve the uniformity of implanted ion distribution near the edge of wafer 20. The Faraday cups 50, 52 may be positioned within guard ring 66 near the periphery of wafer 20 and platen 14.

In operation, wafer 20 is positioned on platen 14. The pressure control system, mass flow controller 38 and gas source 36 produce the desired pressure and gas flow rate within chamber 10. By way of example, the chamber 10 may operate with BF₃ gas at a pressure of 10 millitorr. The pulse source 30 applies a series of high voltage pulses to wafer 20, causing formation of plasma 40 in a plasma discharge region 44 between wafer 20 and anode 24. As known in the art, plasma 40 contains positive ions of the ionizable gas from gas source 36. Plasma 40 includes a plasma sheath 42 in the vicinity, typically at the surface, of wafer 20. The electric field that is present between anode 24 and platen 14 during the high voltage pulse accelerates positive ions from plasma 40 across plasma sheath 42 toward platen 14. The accelerated ions are implanted into wafer 20 to form regions of impurity material. The pulse voltage is selected to implant the positive ions to a desired depth in wafer 20. The number of pulses and the pulse duration are selected to provide a desired dose of impurity material in wafer 20. The current per pulse is a function of pulse voltage, gas pressure and species and any variable position of the electrodes. For example, the cathode-to-anode spacing may be adjusted for different voltages.

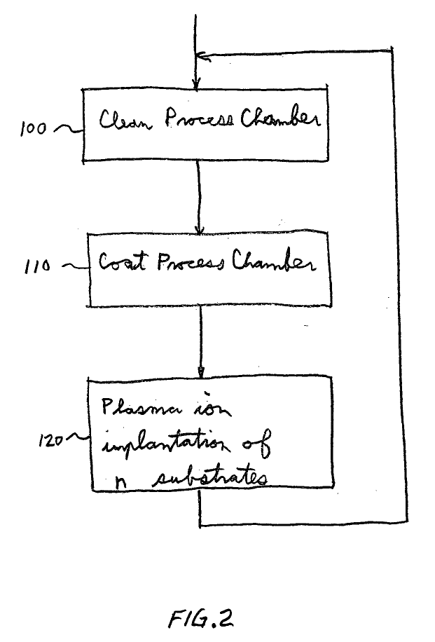

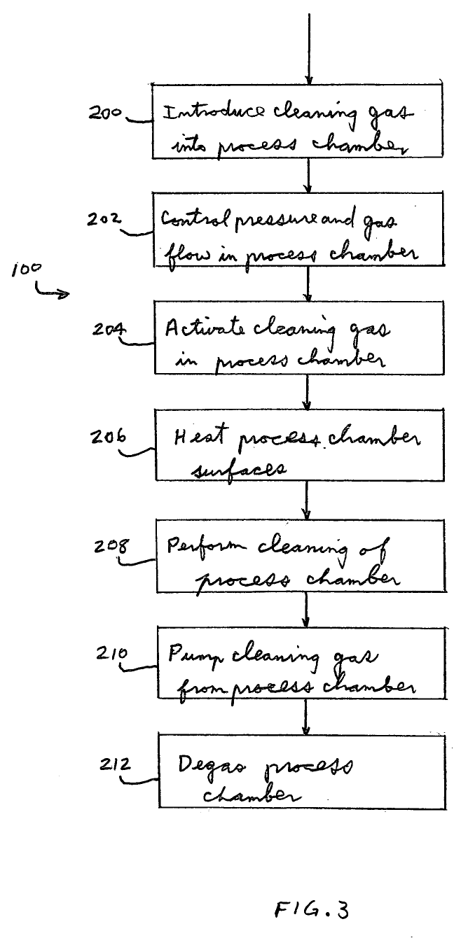

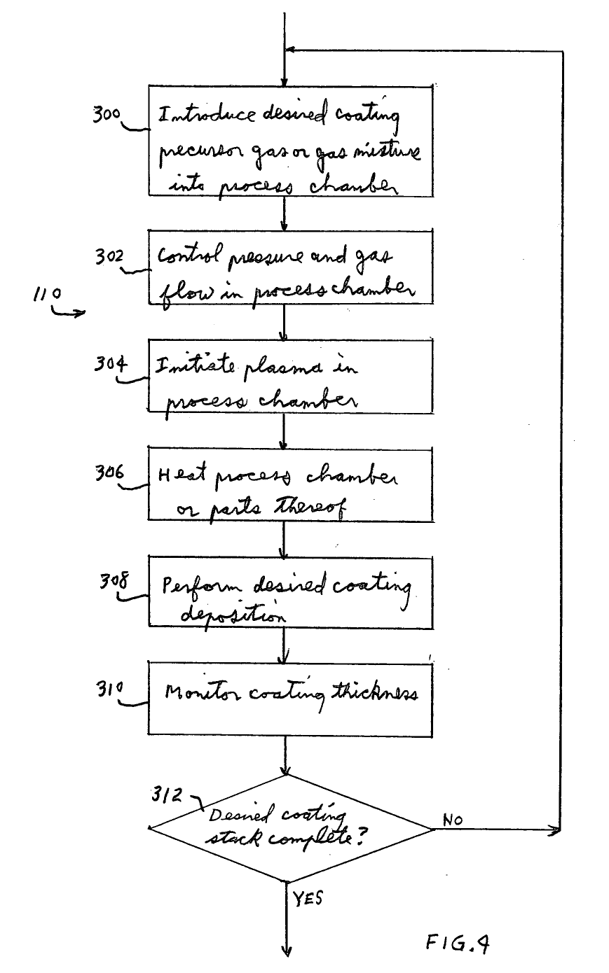

A high-level flow diagram of a process chamber preparation method in accordance with an embodiment of the invention is shown in FIG. 2. The method includes in-situ cleaning of interior surfaces of process chamber 10 in a cleaning process 100 and in-situ coating of interior surfaces of the process chamber 10 in a coating process 110. The process chamber preparation method is followed by plasma implantation of n substrates in a plasma ion implantation process 120. The cleaning and coating processes are then repeated. The cleaning process 100 is described in detail below in connection with FIG. 3, and the coating process 110 is described in detail below in connection with FIG. 4.

The process chamber preparation method includes two main processes run in succession, the first being an in-situ plasma cleaning process and the second being an in-situ coating step to prepare the chamber for a plasma ion implantation process. The process includes cleaning interior surfaces of the process chamber to remove old films and materials from a previous process and depositing a fresh coating that is similar in composition to a film that is deposited during plasma ion implantation. The proper combination and sequencing of processes enables contamination-free plasma ion implantation of substrates with different dopants in one plasma ion implantation system. The cleaning process removes undesirable materials and films from the process chamber, while the coating process provides repeatable processing of the substrates. The chamber preparation method provides improved process flexibility associated with running different dopants in the same plasma ion implantation system. The in-situ chamber preparation method substantially reduces downtime for maintenance and chamber preparation required for repeatable processing of substrates in one process chamber. Additionally, the chamber preparation method may be used to periodically clean the process chamber, removing excess buildup that has occurred on the chamber parts during processing of substrates. For process repeatability, the chamber may be cleaned and coated at optimal intervals to maximize machine throughput and utilization time.

The in-situ cleaning process is effected through the use of a cleaning gas or a mixture of gases that by itself or when activated, either thermally or by a plasma, reacts with dopant deposits in the process chamber to form volatile compounds which can be removed from the chamber by a vacuum pump. The reactive gas mixture may include NF₃, NH₃, O₂, O₃, N₂O, Ar, He, H₂, CF₄, CHF₃, or the like, used alone or in combination. The fluorine-based chemistry, where the active species is a fluorine radical or ion, or molecular fluorine, may be more suitable for chambers using fluorinated dopants, while the hydrogen-based cleaning chemistry may be more suitable in situations where residual fluorine is undesirable.

In typical practice, the film to be removed by the cleaning process includes mainly the dopant material (e.g. B, P or As, etc.) with some substrate material (e.g. Si, Ge, or Ga and As, etc.) which are deposited on the process chamber surfaces during plasma ion implantation of substrates. Such deposits may act as a source of contamination if the process is switched to another dopant or substrate. The film to be removed may also include carbon-based deposits derived from photoresist used on wafers. The cleaning chemistry is determined by the composition of the material being removed, such that the active cleaning agent forms a volatile species upon reaction with the undesired material. For example, a mixture including NF₃, O₂ and Ar may be used to clean the process chamber after a boron doping process using BF₃ gas. The composition of the cleaning gas mixture is selected for optimal cleaning times and cleaning uniformity.

The cleaning gases may be introduced into the process chamber through separate gas ports or one common gas port, and the active cleaning species may be created by coupling RF power and/or DC pulsed bias on the platen to activate the gas mixture and to create a plasma. The concentration of the active species is determined by the coupled RF power or DC pulsed bias and the operating pressure in the chamber. The pressure may be controlled using a variable conductance gate or a throttle valve that has a feedback control circuit with a capacitance manometer, with the flow rate of the gases fixed by mass flow controllers. The pressure may be in a range of about 1 millitorr to 10 torr and is typically in a range of about 100 millitorr to 2 torr. Alternatively, the pressure may be controlled using an upstream pressure controller, with one of the gas lines having a flow meter that can control the proportional flow rates of the other gases. The RF power may be in a range of about 100 watts to 5 kilowatts and is typically about 2 kilowatts. The plasma may also be initiated and maintained by applying a pulsed DC bias on the platen or the chamber walls. In another approach, RF and DC bias may be used simultaneously for initiating and maintaining a plasma. The cleaning action may be enhanced by providing thermal energy to the surfaces being cleaned or by increasing the energy of the impinging species through electric fields between the surface being cleaned and the plasma. This may be accomplished through higher pulsed DC bias on the surface and/or higher voltage on the RF antenna via capacitive coupling.

After the deposits have been removed from the chamber through the action of the cleaning agents, the gases are pumped from the process chamber. The process chamber may be degassed by flowing an inert gas, such as argon or helium, or a passivating gas, such as hydrogen, to remove residual traces of the unwanted elements from the process chamber. The degassing step may also utilize a plasma to enhance the scavenging of residual cleaning gases from the surfaces and also to prepare the chamber for further processing.

A flow diagram of cleaning process 100 in accordance with an embodiment of the invention is shown in FIG. 3. In step 200, a cleaning gas or a mixture of cleaning gases is introduced into the process chamber. The selection of cleaning gas or gases is based on processes previously run in the process chamber and any coatings that have been deposited on surfaces of the process chamber. In step 202, the pressure in the process chamber is controlled at a desired level, typically in a range of about 1 millitorr to 10 torr. The gas flow is also controlled. In step 204, the cleaning gas or cleaning gas mixture is activated in the process chamber. The activation may be produced by initiating and maintaining a plasma in the process chamber, using RF energy, DC pulses, or both. Activation may also be achieved by heating the process chamber, alone or in combination with activation by the plasma. In step 206, process chamber surfaces may optionally be heated to enhance the cleaning process. The heating may be performed with or without a plasma. In step 208, the desired cleaning of the process chamber is performed. The cleaning process may be performed for a selected time or may be terminated using endpoint detection techniques. In step 210, the cleaning gas or cleaning gas mixture and the volatile products of the cleaning process are pumped from the process chamber. In step 212, the process chamber may be degassed with an inert gas, such as argon or helium, or a passivating gas, such as hydrogen. Thermal and/or chemical effects may be utilized for passivation. A plasma may be utilized to enhance the degassing step.

The coating process involves deposition of a coating on interior surfaces of the process chamber as a constituent step in a process sequence or process chamber preparation. The coating improves wafer-to-wafer repeatability and reduces metallic and other forms of contamination that can occur during subsequent plasma ion implantation. In addition, the coating expedites the recovery of the process chamber after maintenance or in-situ plasma cleaning. The in-situ coating may include the material of the substrate being implanted, such as silicon, or a mixture of dopant and substrate materials, where the dopant corresponds to the dopant being implanted in the substrate. One specific example of a coating is boron-containing silicon, wherein the coating is deposited using a mixture of boron precursor gas and a silicon precursor gas. Another coating may include a stack of films, such as a first film of the substrate material and a second film of the dopant material. A film stack may be advantageous in that the underlying layer may be used for determining the end time for a cleaning process and/or as a stopping layer for a cleaning process.

The chamber coating process limits system downtime and limits the risk of contamination of wafers by in-situ coating with a benign material such as the substrate material (silicon, germanium, gallium arsenide, gallium nitride, sapphire, etc.). The coating improves process stability, since the plasma is exposed to the same chamber conditions during every process run. Furthermore, the coating substantially reduces contamination on process wafers by covering a potential contamination source with the benign material, thus protecting the hardware components from exposure to the plasma. The coating also prevents outgassed materials or adsorbed elements in the process chamber from being released into the plasma during plasma ion implantation. The coating process reduces the conditioning time required after maintenance or any cleaning process.

In embodiments where a silicon coating is deposited on interior surfaces of the process chamber, a silicon-containing precursor is introduced into the chamber. A plasma is used to decompose the silicon-containing precursor so as to deposit a silicon-containing coating on the exposed surfaces of the process chamber. The silicon-containing precursor may be a gas such as SiH₄, Si₂H₆, SiF₄ or SiCl₄, or may be an organo-silicon precursor such as trimethylsilane (TMS) or triethylsilane (TES), which may be introduced with an inert gas such as helium, neon, argon or xenon. The silicon material deposition may be controlled further by adding inert or reactive gases to control the composition of the silicon-containing coating. The reactive gases may include hydrogen, oxygen, nitrogen, BF₃, B₂H₆, PH₃, AsF₅, PF₅, PF₃ or arsine to form a doped or undoped coating of a silicon-containing material. This approach may be used with other substrates using different precursor gases containing the appropriate substrate material. For example, GeH₄ or GeF₄ may be used for processing Ge or Si—Ge substrates.

A gas or a gas mixture containing the desired coating species is introduced into the process chamber, and a plasma is initiated. The plasma is run for a sufficient time to produce a desired coating thickness. The coating may have a thickness of about 1-10 micrometers, but is not limited to this thickness range. The coating thickness may be monitored using standard thin-film deposition monitors located in the process chamber. The coating thickness monitors may be left in place to monitor subsequent erosion of the coating and the need for recoating of the process chamber. This may be advantageous in determining the coating thickness required after a cleaning process or the coating process required between subsequent process runs.

When the process chamber is used for plasma ion implantation of substrates with different dopants by switching between processes, the process chamber may require cleaning to remove traces of unwanted dopants and thereby avoid the risk of cross-contamination. Chamber cleaning is a maintenance procedure which results in machine downtime. By depositing on the interior surfaces of the process chamber a coating that contains the new dopant to be implanted, the chamber can be prepared without significant downtime. The coating may be exposed to the process conditions and may be deposited as a dopant film or may act as a source of other atoms through chemical etching and/or physical sputtering mechanisms. In the event that atoms are removed from the coating during processing, these atoms should be either removed from the process mixture or they should be benign to the process. For this reason, the coating preferably has a composition that is close to the composition of the substrate surface during the process. Thus, the coating may include the substrate material and the dopant. The coating may be a single film or a stacked film structure with different compositions in different films.

In typical practice, the coating may include silicon as the substrate material and boron, phosphorus or arsenic as the dopant material. The two materials are provided through in-situ decomposition of precursors under conditions that result in deposition of a coating. The composition of the resulting coating or film stack may be controlled by manipulating the relative ratios of the two precursors. Typical silicon precursors include silanes (SiₙH₂ₙ₊₂, where n=1, 2, 3, . . . ) or organosilanes such as IMS, TES, etc. or halosilanes such SiF₄, SiCl₄, etc., while dopant precursors may be hydrides (such as B₂H₆, PH₃, AsH₃, etc.) or halides (BF₃, BCl₃, PF₃, PF₅, AsF₅, etc.). The coating process may also utilize a diluent gas, such as an inert gas (helium, argon or xenon) or a reactive gas (F₂, Cl₂, H₂, etc.), to control the composition of the coating.

When the coating composition is selected, the coating precursors are introduced into the process chamber in predetermined proportions, the chamber pressure is controlled to a preset value and the plasma is initiated at a desired power to break down the coating precursors. Alternatively, the process chamber or specific parts of the process chamber where the coating is desired may be heated to enable film deposition. Temperature control of the deposition surfaces is not required, but may be advantageous. The coating precursors may be directed into the chamber through one port or through separate ports, and the flow may be directed through nozzles at specific target areas to facilitate desired coating profiles in the process chamber. The coating process is continued until a desired coating thickness is achieved. The coating thickness may be monitored using a standard thin film deposition monitor located in the process chamber. The film stack may be formed by repeating the procedure with different coating precursor compositions. The final film, which is exposed to the process mixture, typically includes mainly the dopant used in the process. For the coating process, it may be advantageous to use the DC pulse bias on the platen and/or the chamber parts to provide additional control over the ion bombardment energy of the coating precursors, which in turn may control coating density and adhesion properties.

A flow diagram of coating process 110 in accordance with an embodiment of the invention is shown in FIG. 4. In step 300, a coating precursor gas or gas mixture is introduced into the process chamber. As noted above, the coating precursor gas may be introduced alone or in combination with an inert gas, a reactive gas, or both. The selection of coating precursor gas is based on a plasma ion implantation process to be run in the process chamber. The coating precursor gas may include the substrate material, the dopant material, or both. In step 302, the pressure and the gas flow in the process chamber are controlled at desired levels. In step 304, a plasma is initiated in process chamber 10. In step 306, interior surfaces or selected interior surfaces of the process chamber may optionally be heated to enhance the coating process. Heating may be performed with a heating element and/or with the plasma. In step 308, the desired coating deposition is performed. In step 310, the coating thickness is monitored. When the coating reaches a desired thickness, the coating process may be terminated or a coating having a different composition may be deposited over the first coating. In step 312, the process returns to step 300 if the desired coating stack is not complete. This process may be repeated to obtain a desired film stack that may contain more than one film layer with varying compositions.

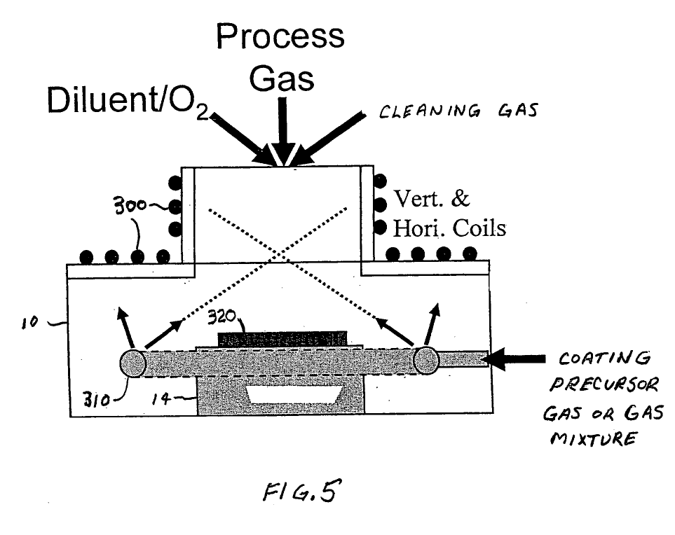

A simplified schematic diagram of a plasma ion implantation process chamber is shown in FIG. 5. Like elements in FIGS. 1 and 5 have the same reference numerals. In the embodiment of FIG. 5, a plasma is initiated and maintained by RF coils 300 coupled to an RF source (not shown). As shown, a process gas may be introduced into process chamber 10 through a port at the top of the chamber. During a cleaning process, cleaning gases, such as NF₃, O₂ and a diluent, may be introduced through the port at the top of the chamber. A hollow ring 310 surrounds platen 14 and may be used for introducing a coating precursor gas into process chamber 10. Hollow ring 310 may be provided with a pattern of holes that permits the coating precursor gas to be directed in preferred directions. In the embodiment of FIG. 5, hollow ring 310 is provided with holes that direct the coating precursor gas toward the upper portions of the process chamber 10 and away from platen 14. This arrangement limits deposition on platen 14. A dummy wafer 320 may be utilized to limit coating of platen 14. It will be understood that hollow ring 310 is shown by way of example only and is not limiting as to the scope of the invention. Any desired arrangement for introducing the coating precursor gas into the process chamber may be utilized. A similar arrangement may be used for a DC pulsed plasma implantation system wherein the plasma is initiated and maintained by the DC bias on the platen and/or the chamber components.

It should be understood that various changes and modifications of the embodiments shown in the drawings described in the specification may be made within the spirit and scope of the present invention. Accordingly, it is intended that all matter contained in the above description and shown in the accompanying drawings be interpreted in an illustrative and not in a limiting sense. The invention is limited only as defined in the following claims and the equivalents thereto.

1. A method for plasma ion implantation of a substrate, comprising:
providing a plasma ion implantation system including a process chamber, a source for producing a plasma in the process chamber, a platen for holding a substrate in the process chamber and a voltage source for accelerating ions from the plasma into the substrate;
depositing on interior surfaces of the process chamber a coating that is compatible with a plasma ion implantation process performed in the process chamber; and
plasma ion implantation of the substrate according to the plasma ion implantation process.

2. A method as defined in claim 1, wherein depositing a coating comprises depositing a coating containing a substrate material.

3. A method as defined in claim 1, wherein depositing a coating comprises depositing a silicon-containing material.

4. A method as defined in claim 1, wherein depositing a coating comprises depositing a coating containing a material selected from the group consisting of Si, Si—Ge, Ge, GaAs, GaN, and sapphire.

5. A method as defined in claim 1, wherein depositing a coating includes introducing a coating precursor into the process chamber.

6. A method as defined in claim 5, wherein depositing a coating further comprises decomposing the coating precursor with the plasma.

7. A method as defined in claim 1, wherein depositing a coating further comprises monitoring a coating thickness during deposition.

8. A method as defined in claim 1, wherein depositing a coating comprises introducing into the process chamber a silicon-containing precursor selected from the group consisting of SiH₄, Si₂H₆, SiF₄, SiCl₄, trimethylsilane, and triethylsilane.

9. A method as defined in claim 8, wherein depositing a coating further comprises introducing an inert gas into the process chamber with the silicon-containing precursor.

10. A method as defined in claim 8, wherein depositing a coating further comprises introducing into the process chamber with the silicon-containing precursor a reactive gas selected from the group consisting of H₂, O₂, N₂, BF₃, B₂H₆, PH₃, AsF₅, PF₅, PF₃, or arsine.

11. A method as defined in claim 8, wherein depositing a coating further comprises introducing into the process chamber with the silicon-containing precursor a reactive gas selected to control a composition of the silicon-containing coating.

12. A method as defined in claim 1, wherein depositing a coating further comprises introducing into the process chamber a coating precursor and a reactive gas in predetermined proportions.

13. A method as defined in claim 1, wherein depositing a coating further comprises controlling one or both of pressure and gas flow in the process chamber during deposition.

14. A method as defined in claim 1, wherein depositing a coating comprises accelerating ions of a coating material to at least one interior surface of the process chamber using a DC pulse.

15. A method as defined in claim 1, wherein depositing a coating comprises injecting a coating precursor through holes in a hollow ring disposed around the platen.

16. A method as defined in claim 1, further comprising cleaning the process chamber before depositing a coating.

17. A method for plasma ion implantation of a substrate, comprising:
providing a plasma ion implantation system including a process chamber, a source for producing a plasma in the process chamber, a platen for holding a substrate in the process chamber and a voltage source for accelerating ions from the plasma into the substrate;
depositing on interior surfaces of the process chamber a dopant-containing coating that is compatible with a plasma ion implantation process performed in the process chamber; and
plasma ion implantation of the substrate according to the plasma ion implantation process.

18. A method as defined in claim 17, wherein the coating has a composition similar to a composition of the substrate surface during plasma ion implantation.

19. A method as defined in claim 17, wherein depositing a coating comprises depositing a coating containing a dopant selected from the group consisting of B, P, As, and Sb.

20. A method as defined in claim 17, wherein depositing a coating comprises introducing a boron-containing precursor gas and a silicon-containing precursor gas into the process chamber.

21. A method as defined in claim 17, wherein the coating comprises two or more layers.

22. A method as defined in claim 17, wherein depositing a coating comprises depositing a layer containing substrate material followed by depositing a dopant-containing layer.

23. A method as defined in claim 17, wherein depositing a dopant-containing coating comprises introducing a hydride dopant precursor into the process chamber.

24. A method as defined in claim 17, wherein depositing a dopant-containing coating comprises introducing a halide dopant precursor into the process chamber.

25. A method as defined in claim 17, wherein depositing a dopant-containing coating comprises introducing a dopant precursor and an inert gas into the process chamber.

26. A method as defined in claim 17, wherein depositing a dopant-containing coating comprises introducing a dopant precursor and a reactive gas into the process chamber.

27. A method as defined in claim 26, wherein introducing the dopant precursor and the reactive gas comprises flowing the dopant precursor and the reactive gas through a single nozzle into the process chamber.

28. A method as defined in claim 26, wherein introducing a dopant precursor and a reactive gas comprises flowing the dopant precursor and the reactive gas through different nozzles into the process chamber.

29. A method as defined in claim 26, wherein introducing a dopant precursor and a reactive gas comprises directing a flow of the dopant precursor and the reactive gas at a target area in the process chamber.

30. A method for plasma ion implantation of a substrate, comprising:
providing a plasma ion implantation system including a process chamber, a source for producing a plasma in the process chamber, a platen for holding a substrate in the process chamber, and a voltage source for accelerating ions from the plasma into the substrate;
cleaning interior surfaces of the process chamber with a cleaning gas that is compatible with a plasma ion implantation process performed in the process chamber; and
plasma ion implantation of the substrate according to the plasma ion implantation process.

31. A method as defined in claim 30, further comprising activating the cleaning gas with the plasma.

32. A method as defined in claim 30, further comprising thermally activating the cleaning gas.

33. A method as defined in claim 30, wherein the cleaning gas is selected from a group consisting of NF₃, NH₃, O₂, O₃, N₂O, Ar, He, H₂, CF₄, CHF₃, and combinations thereof.

34. A method as defined in claim 30, wherein the cleaning gas is selected for compatibility with the plasma ion implantation process.

35. A method as defined in claim 30, wherein cleaning interior surfaces of the process chamber is performed before depositing a fresh coating on interior surfaces of the process chamber.

36. A method as defined in claim 30, wherein a fluorine-based cleaning gas is used following plasma ion implantation with fluorinated dopants.

37. A method as defined in claim 30, wherein a hydrogen-based cleaning gas is used in applications where residual fluorine is undesirable.

38. A method as defined in claim 30, wherein a cleaning gas including a mixture of NF₃, O₂, and Ar is used after plasma ion implantation of boron using BF₃.

39. A method as defined in claim 30, wherein cleaning interior surfaces of the process chamber comprises controlling a pressure in the process chamber in a range of about 1 millitorr to 10 torr.

40. A method as defined in claim 30, wherein cleaning interior surfaces of the process chamber comprises controlling pressure in the process chamber in a range of about 100 millitorr to 2 torr.

41. A method as defined in claim 30, wherein cleaning interior surfaces of the process chamber comprises activating the cleaning gas with a plasma generated by RF energy in a range of about 100 watts to 5 kilowatts.

42. A method as defined in claim 30, wherein cleaning interior surfaces of the process chamber comprises activating the cleaning gas with a plasma generated by DC pulses.

43. A method as defined in claim 30, wherein cleaning interior surfaces of the process chamber comprises heating one or more surfaces of the process chamber.

44. A method as defined in claim 30, wherein cleaning interior surfaces of the process chamber comprises activating the cleaning gas with a plasma generated by a combination of RF energy and DC pulses.

45. A method as defined in claim 30, wherein cleaning interior surfaces of the process chamber comprises providing electric fields in the process chamber for acceleration of ions of the cleaning gas.

46. A method as defined in claim 30, wherein cleaning interior surfaces of the process chamber further includes degassing the process chamber with an inert gas.

47. A method as defined in claim 30, wherein cleaning interior surfaces of the process chamber further includes degassing the process chamber with a passivating gas.

48. A method for plasma ion implantation of a substrate, comprising:
providing a plasma ion implantation system including a process chamber, a source for producing a plasma in the process chamber, a platen for holding a substrate in the process chamber, and a voltage source for accelerating ions from the plasma into the substrate;
depositing on interior surfaces of the process chamber a fresh coating that is similar in composition to a deposited film that results from plasma ion implantation of the substrate;
before depositing the fresh coating, cleaning interior surfaces of the process chamber by removing an old film using one or more activated cleaning precursors;
plasma ion implantation of the substrate according to a plasma ion implantation process; and
repeating the steps of cleaning interior surfaces of the process chamber and depositing a fresh coating following plasma ion implantation of one or more substrates.

49. A plasma ion implantation system comprising:
a process chamber;
a source for producing a plasma in the process chamber;
a platen for holding a substrate in the process chamber;
a pulse source for generating implant pulses for accelerating ions from the plasma into the substrate; and
means for depositing on interior surfaces of the process chamber a coating that is compatible with a plasma ion implantation process performed in the process chamber.

50. A plasma ion implantation system comprising:
a process chamber;
a source for producing a plasma in the process chamber;
a platen for holding a substrate in the process chamber;
a pulse source for generating implant pulses for accelerating ions from the plasma into the substrate; and
means for depositing on interior surfaces of the process chamber a dopant-containing coating that is compatible with a plasma ion implantation process performed in the process chamber.

51. A plasma ion implantation system comprising:
a process chamber;
a source for producing a plasma in the process chamber;
a platen for holding a substrate in the process chamber;
a pulse source for generating implant pulses for accelerating ions from the plasma into the substrate; and
means for cleaning interior surfaces of the process chamber with a cleaning gas that is compatible with a plasma ion implantation process performed in the process chamber.

52. A plasma ion implantation system comprising:
a process chamber;
a source for producing a plasma in the process chamber;
a platen for holding a substrate in the process chamber;
a pulse source for generating implant pulses for accelerating ions from the plasma into the substrate;
means for depositing on an interior surface of the process chamber a fresh coating that is similar in composition to a deposited film that results from plasma ion implantation of the substrate; and
means for cleaning interior surfaces of the process chamber, before depositing the fresh coating, by removing an old film using one or more activated cleaning precursors.
